(19) United States
(12) Patent Application Publication
(10) Pub. No.: US 2017/0110495 A1
(43) Pub. Date: Apr. 20, 2017

(54) CHIP PACKAGE AND MANUFACTURING METHOD THEREOF

(71) Applicant: XINTEC INC., Taoyuan City (TW)

(72) Inventors: Jyun-Liang WU, Taichung City (TW); Chia-Sheng LIN, Taoyuan City (TW); Po-Han LEE, Taipei City (TW); Yen-Shih HO, Kaohsiung City (TW)

(21) Appl. No.: 15/277,184

(22) Filed: Sep. 27, 2016

Related U.S. Application Data
(60) Provisional application No. 62/242,502, filed on Oct. 16, 2015.

(51) Int. Cl. H01L 27/146; H01L 21/56; H01L 23/00

(52) U.S. Cl. CPC H01L 27/14618; H01L 24/08; H01L 24/03; H01L 21/563; H01L 2224/0237; H01L 2224/0231

(57) ABSTRACT

A chip package includes a chip, a dam element, and a height-increasing element. The chip has an image sensing area, a first surface, and a second surface opposite to the first surface. The image sensing area is located on the first surface of the chip. The dam element is located on the first surface of the chip and surrounds the image sensing area. The height-increasing element is located on the dam element, such that the dam element is between the height-increasing element and the chip.

### RELATED APPLICATIONS

This application claims priority to U.S. provisional Application Ser. No. 62/242,502, filed Oct. 16, 2015, which is herein incorporated by reference.

### BACKGROUND

Field of Invention

The present invention relates to a chip package and a manufacturing method of the chip package.

Description of Related Art

In manufacturing a chip package (e.g., a CMOS chip) of an image sensor, a glass sheet is often used to cover a surface of a chip, thereby protecting an image sensing area of the chip. In a typical chip package having a glass sheet, the thickness of a dam element that is disposed between the chip and the glass sheet is the same as a distance between the glass sheet and the chip, such as about in a range from 40 μm to 45 μm. Therefore, when the image sensing area receives an image, a lens flare issue is prone to occur.

In the manufacturing processes of an image sensor, if there is no glass sheet disposed on a wafer which is not yet cut to form a plurality of chips, when the wafer is thin, it is difficult to remove the wafer which has a ball grid array due to process limitations. Moreover, image sensing areas of the wafer may easily be contaminated during the manufacturing processes, such that it is difficult to improve the yield of the chip package.

### SUMMARY

An aspect of the present invention is to provide a chip package.

According to an embodiment of the present invention, a chip package includes a chip, a dam element, and a height-increasing element. The chip has an image sensing area, a first surface, and a second surface opposite to the first surface. The image sensing area is located on the first surface of the chip. The dam element is located on the first surface of the chip and surrounds the image sensing area. The height-increasing element is located on the dam element, such that the dam element is between the height-increasing element and the chip.

Another aspect of the present invention is to provide a manufacturing method of a chip package.

According to an embodiment of the present invention, a manufacturing method of a chip package includes the following steps. A supporting block is etched, such that the supporting block has a recess. A light transmissive sheet is bonded to the supporting block to close the recess. The supporting block is ground, such that a bottom of the recess is removed to form a height-increasing element. A side of the height-increasing element facing away from the light transmissive sheet is bonded to a dam element that is located on a wafer, and the dam element surrounds an image sensing area of the wafer.

Another aspect of the present invention is to provide a manufacturing method of a chip package.

According to an embodiment of the present invention, a manufacturing method of a chip package includes the following steps. A light transmissive sheet is bonded to a supporting block. The supporting block is etched, such that a central region of the supporting block is removed to form a height-increasing element. A side of the height-increasing element facing away from the light transmissive sheet is bonded to a dam element that is located on a wafer, and the dam element surrounds an image sensing area of the wafer.

In the aforementioned embodiment of the present invention, since the chip package includes the dam element and the height-increasing element, and the height-increasing element is located on the dam element, the sum of the heights of the stacked dam element and height-increasing element is large. As a result of such a design, the dam element and the height-increasing element are capable of shielding light, thereby preventing the image sensing area from receiving external random light (i.e., light which is not from a target object) which may cause interference. In addition, when a light transmissive sheet is disposed on the height-increasing element, since sum of the height of the dam element and the height of the height-increasing element is large, a distance between the light transmissive sheet and the chip is increased. As a result, when the image sensing area receives an image, a flare issue does not easily occur.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiments, with reference made to the accompanying drawings as follows:

FIG. 1 is a cross-sectional view of a chip package according to one embodiment of the present invention;

FIG. 2 is a cross-sectional view of a chip package according to one embodiment of the present invention;

FIG. 3 is a flow chart of a manufacturing method of a chip package according to one embodiment of the present invention;

FIG. 4 is a cross-sectional view of a supporting block after being etched according to one embodiment of the present invention;

FIG. 5 is a cross-sectional view of the supporting block shown in FIG. 4 after being bonded to a light transmissive sheet;

FIG. 6 is a cross-sectional view of the supporting block shown in FIG. 5 after being ground;

FIG. 7 is a cross-sectional view of a height-increasing element shown in FIG. 6 after being bonded to a wafer;

FIG. 8 is a flow chart of a manufacturing method of a chip package according to one embodiment of the present invention;

FIG. 9 is a cross-sectional view of a light transmissive sheet after being bonded to a supporting block according to one embodiment of the present invention;

FIG. 10 is a cross-sectional view of the supporting block shown in FIG. 9 after being etched;

FIG. 11 is a cross-sectional view of a height-increasing element shown in FIG. 10 after being bonded to a wafer;

FIG. 12 is a cross-sectional view of a chip package according to one embodiment of the present invention; and

FIG. 13 is a cross-sectional view of a chip package according to one embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

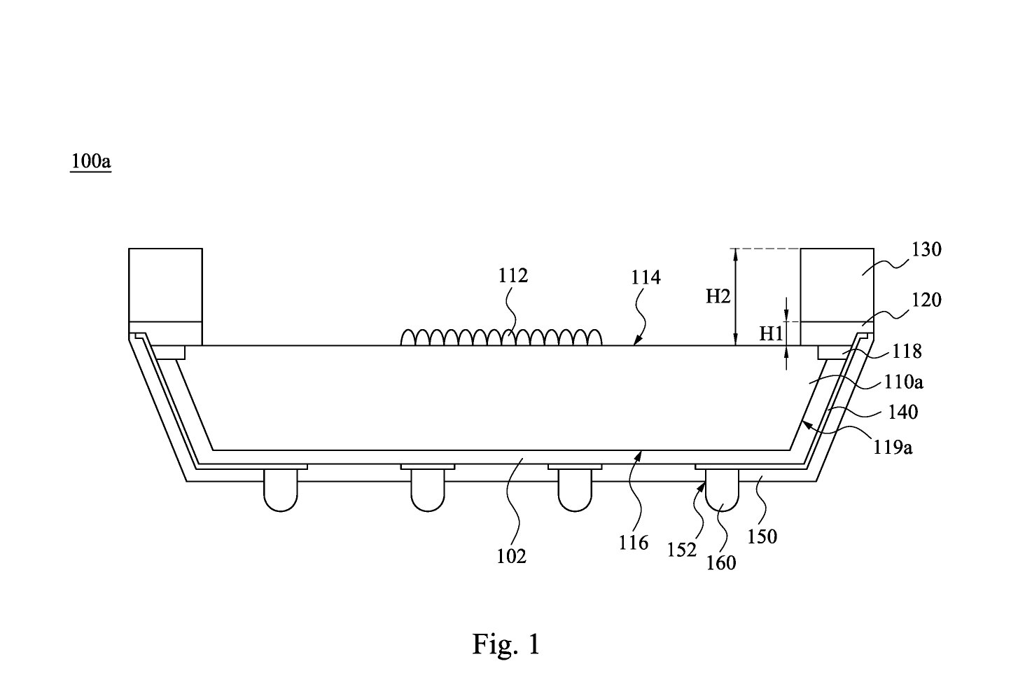

FIG. 1 is a cross-sectional view of a chip package 100a according to one embodiment of the present invention. As shown in FIG. 1, the chip package 100a includes a chip 110a, a dam element 120, and a height-increasing element 130. The chip 110a has an image sensing area 112, a first surface 114, and a second surface 116 that is opposite to the first surface 114. The image sensing area 112 is located on the first surface 114 of the chip 110a. The dam element 120 is located on the first surface 114 of the chip 110a and surrounds the image sensing area 112. The height-increasing element 130 is located on the dam element 120, such that the dam element 120 is present between the height-increasing element 130 and the chip 110a.

In this embodiment, the height H1 of the dam element 120 is in a range from 40 μm to 45 μm. The sum of the height of the height-increasing element 130 and the height of the dam element 120 (i.e., H2) is in a range from 150 μm to 200 μm. The height-increasing element 130 may be made of a material including silicon or polymer. Since the chip package 100a includes the dam element 120 and the height-increasing element 130, and the height-increasing element 130 is located on the dam element 120, the sum of the height of the stacked dam element 120 and height-increasing element 130 (i.e., H2) is large. As a result of such a design, the dam element 120 and the height-increasing element 130 are capable of shielding light, thereby preventing the image sensing area 112 from receiving external random light (i.e., light which is not from a target object) to cause interference. For example, the height-increasing element 130 at the right side of FIG. 1 may shield extremely oblique ambient light that is from the right side of the right height-increasing element 130, such that the ambient light does not transmit to the image sensing area 112.

The chip 110a has a conductive pad 118 and a concave portion 119a. The conductive pad 118 is located on the first surface 114 of the chip 110a, and the conductive pad 118 is exposed through the concave portion 119a. In this embodiment, the concave portion 119a is an oblique surface that is present adjacent to the first and second surfaces 114, 116. The chip package 100a further includes a redistribution layer 140. The redistribution layer 140 is located on the second surface 116 of the chip 110a, a sidewall of the concave portion 119a, and the conductive pad 118. In this embodiment, the chip package 100a further includes an isolation layer 102. The isolation layer 102 is present between the chip 110a and the redistribution layer 140, and covers the second surface 116 and the sidewall of the concave portion 119a.

Moreover, the chip package 100a further includes a passivation layer 150 and a conductive structure 160. The passivation layer 150 covers the redistribution layer 140 and a portion of the isolation layer 102. The passivation layer 150 has an opening 152, such that a portion of the redistribution layer 140 may be exposed through the opening 152. The conductive structure 160 is located on the redistribution layer 140 that is in the opening 152 of the passivation layer 150, thereby electrically connecting the conductive structure 160 and the conductive pad 118 through the redistribution layer 140. The conductive structure 160 may be a conductive pillar, a conductive bump, or a solder ball of a ball grid array (BGA), but the present invention is not limited in this regard.

It is to be noted that the connection relationships and materials of the aforementioned elements will not be repeated in the following description. In the following description, other types of chip packages will be described.

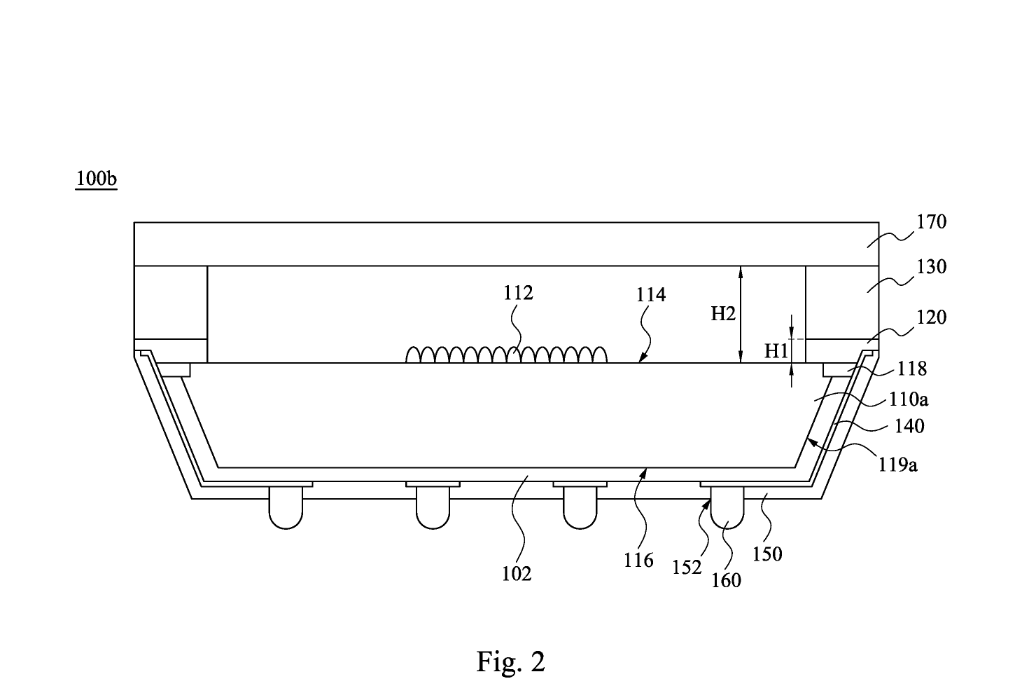

FIG. 2 is a cross-sectional view of a chip package 100b according to one embodiment of the present invention. The chip package 100b includes the chip 110a, the dam element 120, and the height-increasing element 130. The difference between this embodiment and the embodiment shown in FIG. 1 is that the chip package 100b further includes a light transmissive sheet 170. The light transmissive sheet 170 is located on the height-increasing element 130, such that the height-increasing element 130 is present between the light transmissive sheet 170 and the dam element 120. In other words, the light transmissive sheet 170 is located on a surface of the height-increasing element 130 facing away from the dam element 120. The light transmissive sheet 170 may protect the image sensing area 112 of the chip 110a to prevent the image sensing area 112 from being polluted by dust and to prevent moisture from entering the image sensing area 112.

In this embodiment, since sum of the height of the dam element 120 and the height of the height-increasing element 130 (i.e., H2) is large, a distance between the light transmissive sheet 170 and the chip 110a is increased and is substantially the same as the sum of the heights H2. As a result, when the image sensing area 112 receives an image, a lens flare issue does not easily occur, thereby improving the clarity of the image.

In the following description, the manufacturing methods of the chip packages shown 100a shown in FIG. 1 and the chip package 100b shown in FIG. 2 will be described.

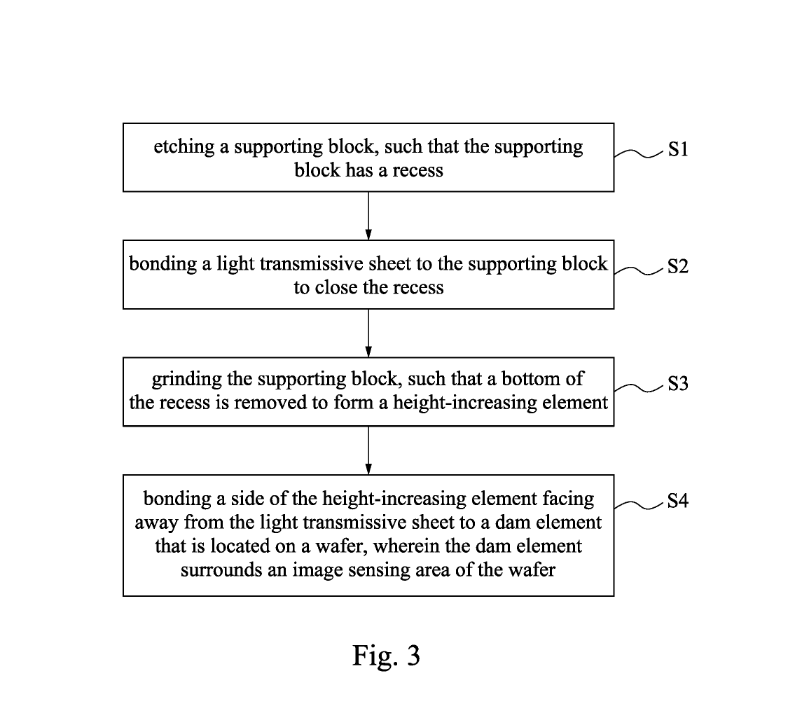

FIG. 3 is a flow chart of a manufacturing method of a chip package according to one embodiment of the present invention. The manufacturing method of the chip package includes the following steps. In step S1, a supporting block is etched, such that the supporting block has a recess. Thereafter, in step S2, a light transmissive sheet is bonded to the supporting block to close the recess. Afterwards, in step S3, the supporting block is ground, such that a bottom of the recess is removed to form a height-increasing element. Subsequently, in step S4, a side of the height-increasing element facing away from the light transmissive sheet is bonded to a dam element that is located on a wafer, and the dam element surrounds an image sensing area of the wafer. In the following description, the aforementioned steps will be described in detail.

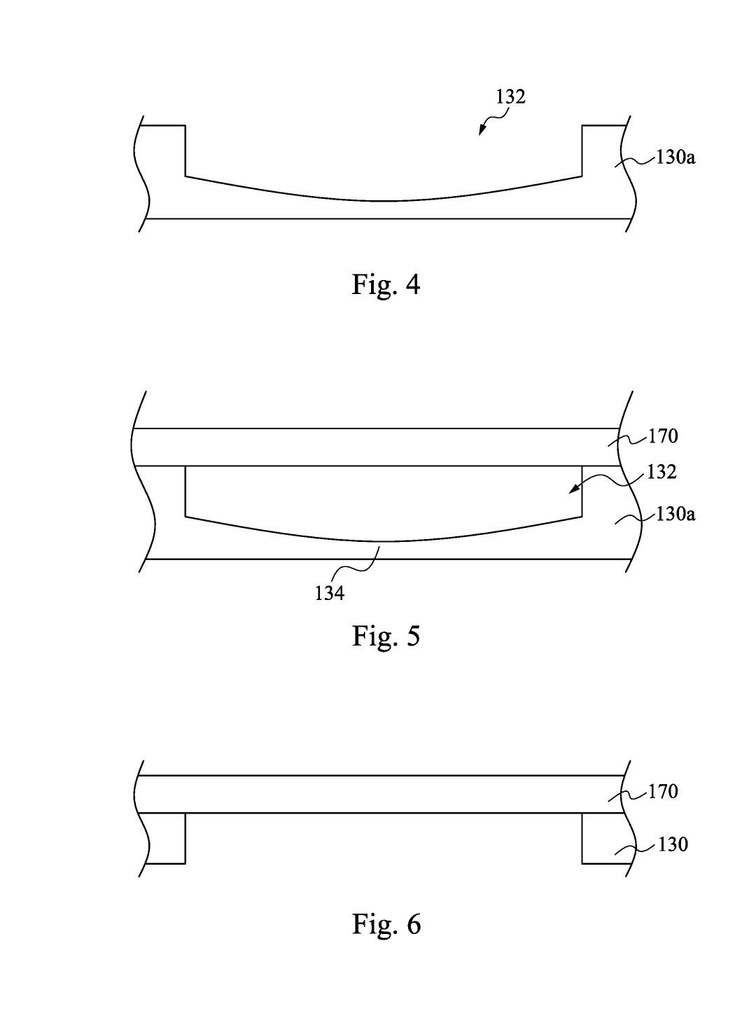

FIG. 4 is a cross-sectional view of a supporting block 130a after being etched according to one embodiment of the present invention. FIG. 5 is a cross-sectional view of the supporting block 130a shown in FIG. 4 after being bonded to the light transmissive sheet 170. As shown in FIG. 4 and FIG. 5, after the supporting block 130a is etched, the supporting block 130a may have a recess 132. After the recess 132 is formed, the light transmissive sheet 170 may be bonded to the supporting block 130a, such that the recess 132 is closed by the light transmissive sheet 170 and the supporting block 130a.

FIG. 6 is a cross-sectional view of the supporting block 130a shown in FIG. 5 after being ground. As shown in FIG. 5 and FIG. 6, after the light transmissive sheet 170 is bonded to the supporting block 130a, the supporting block 130a may be ground, such that the bottom 134 of the recess 132 is removed so as to form the height-increasing element 130.

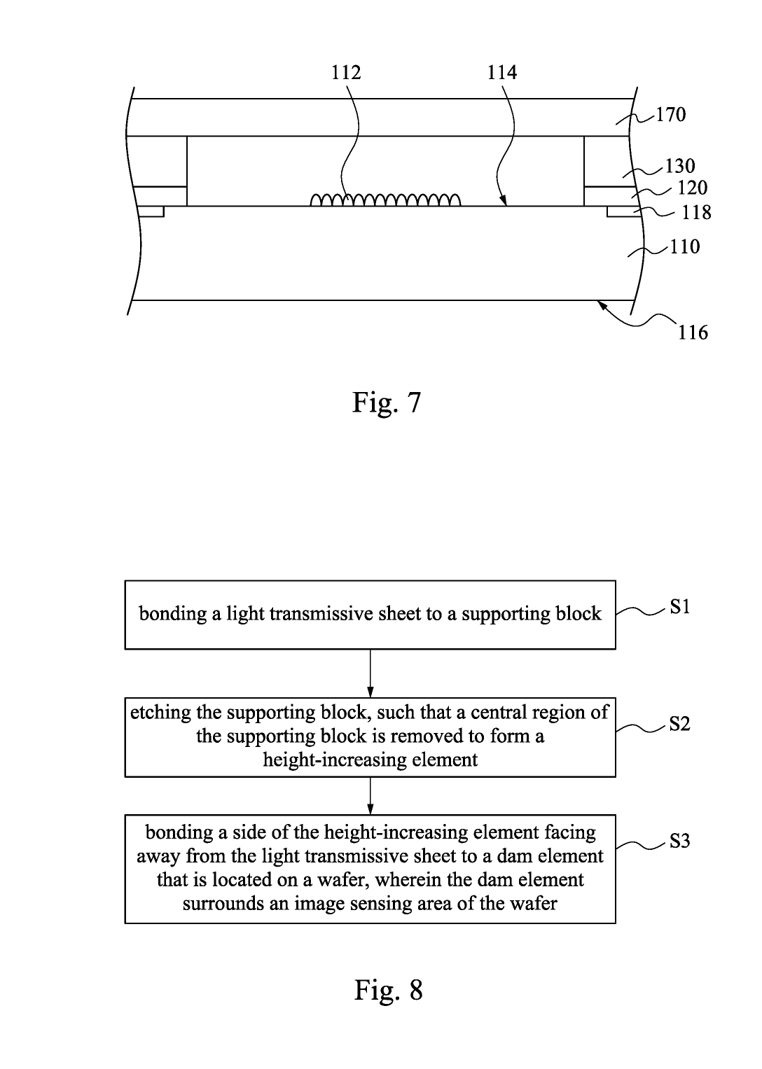

FIG. 7 is a cross-sectional view of the height-increasing element 130 shown in FIG. 6 after being bonded to a wafer 110. As shown in FIG. 6 and FIG. 7, the wafer 110 is referred to as a semiconductor element that may be diced to form plural chips 110a (see FIG. 1 or FIG. 2). After the height-increasing element 130 shown in FIG. 6 is formed, a side of the height-increasing element 130 facing away from the light transmissive sheet 170 may be bonded to the dam element 110 that is located on the wafer 110. The dam element 120 surrounds the image sensing area 112 of the wafer 110. In the subsequent manufacturing processes, the light transmissive sheet 170 may provide a supporting force to prevent the wafer 110 from being broken due to an external force. In addition, the light transmissive sheet 170 may protect the image sensing area 112 to prevent the image sensing area 112 from pollution of dust or process liquid.

As shown in FIG. 2 and FIG. 7, after the structure of FIG. 7 is formed, if the wafer 110 is thick, a grinding process may be performed to the second surface 116 of the wafer 110 in advance to decrease the thickness of the wafer 110, but the present invention is not limited in this regard. Thereafter, the second surface 116 of the wafer 110 may be patterned to form the concave portion 119a, such that the conductive pad 118 on the first surface 114 of the wafer 110 is exposed through the concave portion 119a. Afterwards, the redistribution layer 140 may be formed on the second surface 116 of the wafer 110, the sidewall of the concave portion 119a, and the conductive pad 118. After the redistribution layer 140 is formed, the passivation layer 150 may be formed to cover the redistribution layer 140. Thereafter, the passivation layer 150 may be patterned to form the opening 152, such that a portion of the redistribution layer 140 is exposed through the opening 152. Next, the conductive structure 160 may be formed on the redistribution layer 140 that is in the opening 152.

After the conductive structure 160 is formed, the light transmissive sheet 170, the height-increasing element 130, the dam element 120, and the wafer 110 may be cut in a vertical direction to form the chip package 100b of FIG. 2. After that, the light transmissive sheet 170 may be removed from the dam element 120 to obtain the chip package 100a of FIG. 1. Designers may decide whether the light transmissive sheet 170 is removed or not as they deem necessary, and the present invention is not limited in this regard. Moreover, in another embodiment, the light transmissive sheet 170 may be removed earlier, and then the height-increasing element 130, the dam element 120, and the wafer 110 are cut in a vertical direction to obtain the chip package 100a of FIG. 1.

FIG. 8 is a flow chart of a manufacturing method of a chip package according to one embodiment of the present invention. The manufacturing method of the chip package includes the following steps. In step S1, a light transmissive sheet is bonded to a supporting block. Thereafter, in step S2, the supporting block is etched, such that a central region of the supporting block is removed to form a height-increasing element. Subsequently, in step S3, a side of the height-increasing element facing away from the light transmissive sheet is bonded to a dam element that is located on a wafer, and the dam element surrounds an image sensing area of the wafer. In the following description, the aforementioned steps will be described in detail.

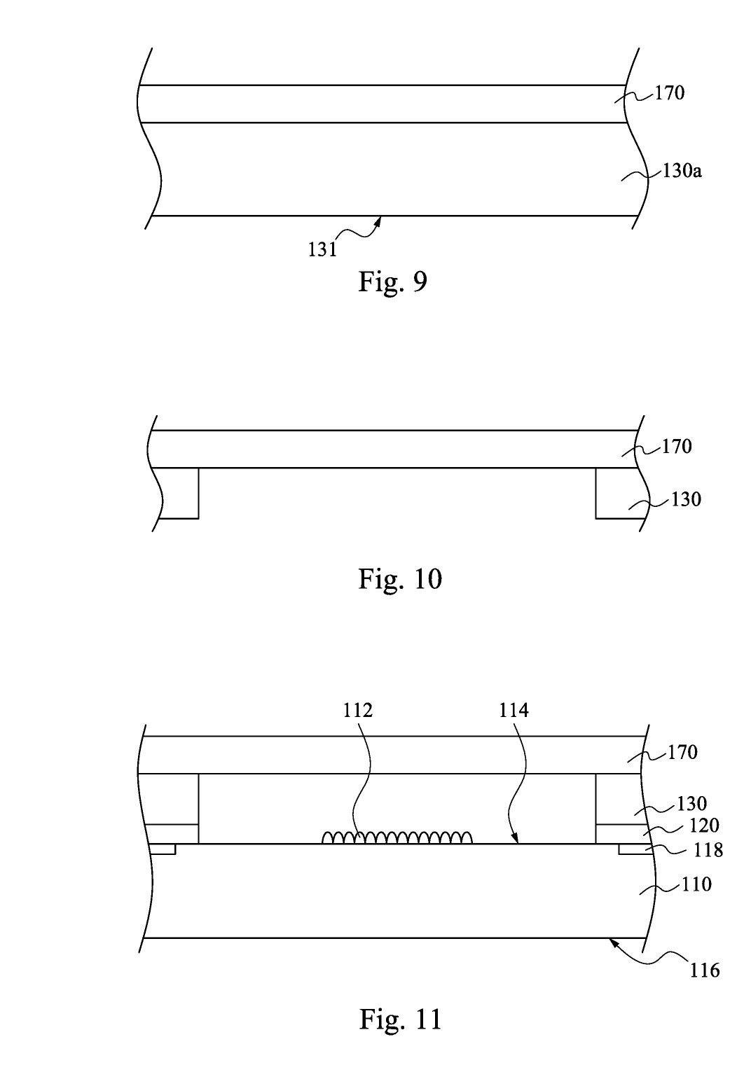

FIG. 9 is a cross-sectional view of the light transmissive sheet 170 after being bonded to the supporting block 130a according to one embodiment of the present invention. FIG. 10 is a cross-sectional view of the supporting block 130a shown in FIG. 9 after being etched. As shown in FIG. 9 and FIG. 10, after the light transmissive sheet 170 is bonded to the supporting block 130a, the supporting block 130a may be etched, such that the central region 131 of the supporting block 130a is removed to form the height-increasing element 130.

FIG. 11 is a cross-sectional view of the height-increasing element 130 shown in FIG. 10 after being bonded to the wafer 110. As shown in FIG. 10 and FIG. 11, after the height-increasing element 130 is formed, a side of the height-increasing element 130 facing away from the light transmissive sheet 170 may be bonded to the dam element 120 that is located on the wafer 110. The dam element 120 surrounds the image sensing area 112 of the wafer 110.

The subsequent manufacturing processes after FIG. 11 are similar to the subsequent manufacturing processes after FIG. 7, and thus will not be described again. In other words, after the structure of FIG. 11 is applied through patterning the wafer 110, forming the redistribution layer 140, the passivation layer 150, and the conductive structure 160, and the cutting process, the chip package 100a shown in FIG. 1 or the chip package 100b shown in FIG. 2 may be obtained. Designers may decide whether the light transmissive sheet 170 is removed or not as they deem necessary, and the present invention is not limited in this regard.

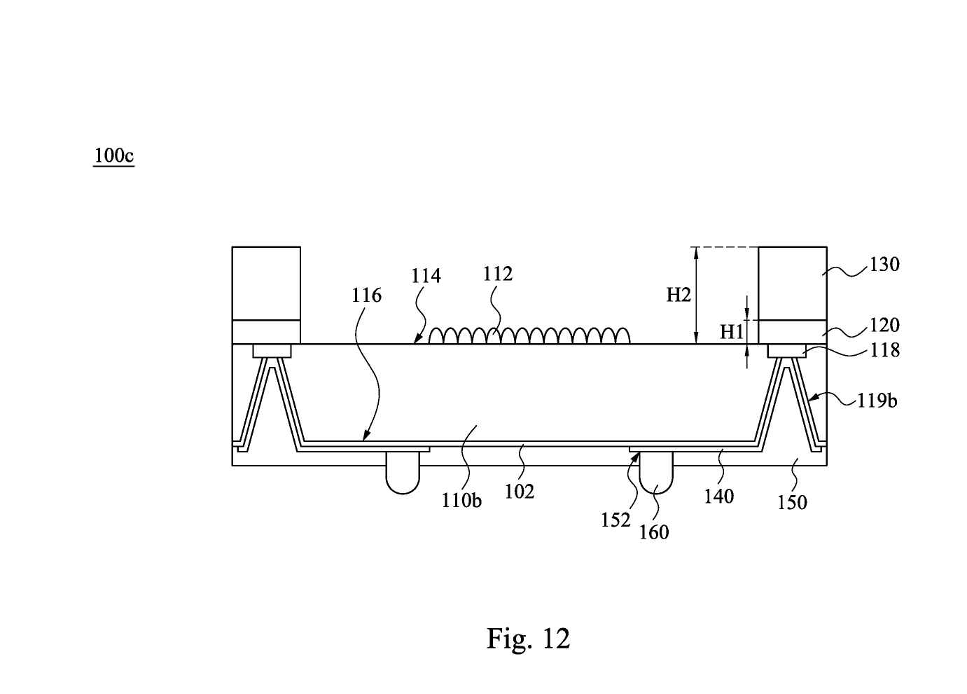

FIG. 12 is a cross-sectional view of a chip package 100c according to one embodiment of the present invention. The chip package 100c includes the chip 110b, the dam element 120, and the height-increasing element 130. The chip 110b has the conductive pad 118 and a concave portion 119b. The difference between this embodiment and the embodiment shown in FIG. 1 is that the concave portion 119b is a hole that is recessed in the second surface 116 of the chip 110b. In this embodiment, the chip package 100c may be manufactured by utilizing the manufacturing method shown in FIG. 3 or FIG. 8.

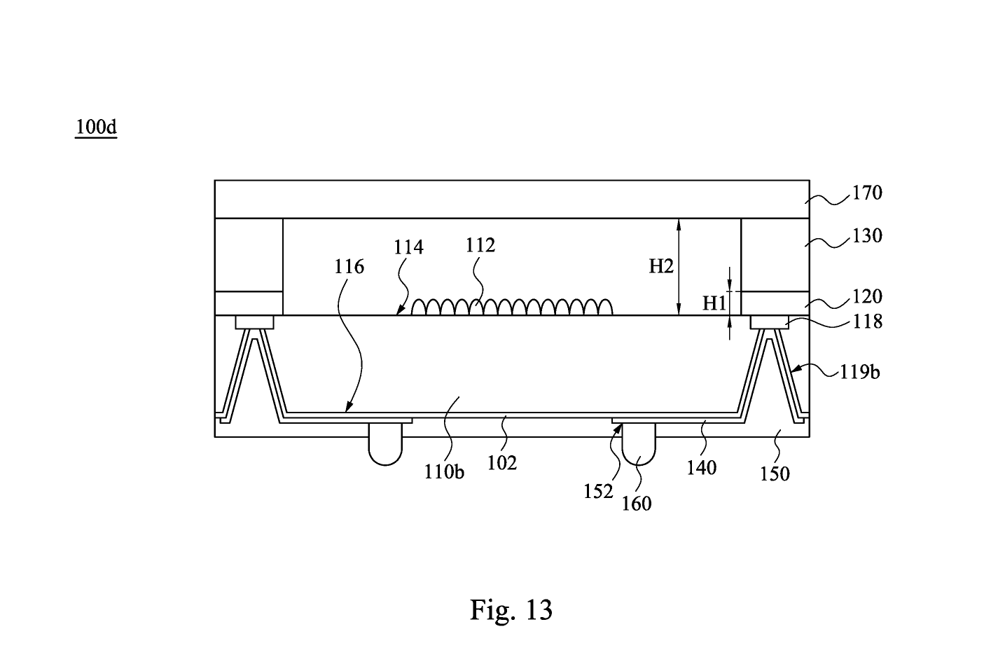

FIG. 13 is a cross-sectional view of a chip package 100d according to one embodiment of the present invention. The chip package 100d includes the chip 110b, the dam element 120, and the height-increasing element 130. The difference between this embodiment and the embodiment shown in FIG. 12 is that the chip package 100d further includes the light transmissive sheet 170. The light transmissive sheet 170 is located on the height-increasing element 130, such that the height-increasing element 130 is present between the light transmissive sheet 170 and the dam element 120. In this embodiment, the chip package 100d may be manufactured by utilizing the manufacturing method shown in FIG. 3 or FIG. 8.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention covers modifications and variations of this invention provided they fall within the scope of the following claims.

What is claimed is:

1. A chip package, comprising:
a chip having an image sensing area, a first surface, and a second surface that is opposite to the first surface, wherein the image sensing area is located on the first surface;
a dam element located on the first surface of the chip and surrounding the image sensing area; and
a height-increasing element located on the dam element, such that the dam element is present between the height-increasing element and the chip.

2. The chip package of claim 1, wherein a sum of a height of the height-increasing element and a height of the dam element is in a range from 150 μm to 200 μm.

3. The chip package of claim 1, wherein the height-increasing element is made of a material including silicon or polymer.

4. The chip package of claim 1, wherein a height of the dam element is in a range from 40 μm to 45 μm.

5. The chip package of claim 1, further comprising:
a light transmissive sheet located on the height-increasing element, such that the height-increasing element is present between the light transmissive sheet and the dam element.

6. The chip package of claim 1, wherein the chip has a conductive pad and a concave portion, and the conductive pad is located on the first surface of the chip, and the conductive pad is exposed through the concave portion, and the chip package further comprises:
a redistribution layer located on the second surface of the chip, a sidewall of the concave portion, and the conductive pad.

7. The chip package of claim 6, further comprising:
a passivation layer covering the redistribution layer.

8. The chip package of claim 7, wherein the passivation layer has an opening to expose the redistribution layer, and the chip package further comprises:
a conductive structure located on the redistribution layer that is in the opening.

9. The chip package of claim 6, wherein the concave portion is an oblique surface that is present adjacent to the first and second surfaces.

10. The chip package of claim 6, wherein the concave portion is a hole that is recessed in the second surface of the chip.

11. A manufacturing method of a chip package, comprising:
etching a supporting block, such that the supporting block has a recess;
bonding a light transmissive sheet to the supporting block to close the recess;
grinding the supporting block, such that a bottom of the recess is removed to form a height-increasing element; and
bonding a side of the height-increasing element facing away from the light transmissive sheet to a dam element that is located on a wafer, wherein the dam element surrounds an image sensing area of the wafer.

12. The manufacturing method of claim 11, wherein the wafer has a first surface, and a second surface that is opposite to the first surface, and the image sensing area is located on the first surface, and the manufacturing method further comprises:
patterning the second surface of the wafer to form a concave portion, such that a conductive pad on the first surface is exposed through the concave portion.

13. The manufacturing method of claim 12, further comprising:
forming a redistribution layer on the second surface of the wafer, a sidewall of the concave portion, and the conductive pad.

14. The manufacturing method of claim 13, further comprising:
forming a passivation layer to cover the redistribution layer.

15. The manufacturing method of claim 14, further comprising:
patterning the passivation layer to form an opening, such that a portion of the redistribution layer is exposed through the opening; and
forming a conductive structure on the redistribution layer that is in the opening.

16. The manufacturing method of claim 15, further comprising:
cutting the light transmissive sheet, the height-increasing element, the dam element, and the wafer in a vertical direction to form the chip package.

17. The manufacturing method of claim 11, further comprising:
removing the light transmissive sheet.

18. The manufacturing method of claim 17, further comprising:
cutting the height-increasing element, the dam element, and the wafer in a vertical direction to form the chip package.

19. A manufacturing method of a chip package, comprising:
bonding a light transmissive sheet to a supporting block;
etching the supporting block, such that a central region of the supporting block is removed to form a height-increasing element; and
bonding a side of the height-increasing element facing away from the light transmissive sheet to a dam element that is located on a wafer, wherein the dam element surrounds an image sensing area of the wafer.

20. The manufacturing method of claim 19, wherein the wafer has a first surface, and a second surface that is opposite to the first surface, and the image sensing area is located on the first surface, and the manufacturing method further comprises:
patterning the second surface of the wafer to form a concave portion, such that a conductive pad on the first surface is exposed through the concave portion.

21. The manufacturing method of claim 20, further comprising:
forming a redistribution layer on the second surface of the wafer, a sidewall of the concave portion, and the conductive pad.

22. The manufacturing method of claim 21, further comprising:
forming a passivation layer to cover the redistribution layer.

23. The manufacturing method of claim 22, further comprising:
patterning the passivation layer to form an opening, such that a portion of the redistribution layer is exposed through the opening; and
forming a conductive structure on the redistribution layer that is in the opening.

24. The manufacturing method of claim 19, further comprising:
cutting the light transmissive sheet, the height-increasing element, the dam element, and the wafer in a vertical direction to form the chip package.

25. The manufacturing method of claim 19, further comprising:
removing the light transmissive sheet.

26. The manufacturing method of claim 25, further comprising:
cutting the height-increasing element, the dam element, and the wafer in a vertical direction to form the chip package.
